(19) United States
(12) Patent Application Publication
(10) Pub. No.: US 2024/0324273 A1
(43) Pub. Date: Sep. 26, 2024

(54) DISPLAY APPARATUSES AND DISPLAY PANELS

(71) Applicant: BOE Technology Group Co., Ltd., Beijing (CN)

(72) Inventors: Qingyu HUANG, Beijing (CN); Zhiqiang JIAO, Beijing (CN); Wenqi LIU, Beijing (CN)

(21) Appl. No.: 18/028,346

(22) PCT Filed: Apr. 29, 2022
(86) PCT No.: PCT/CN2022/090357

§ 371 Date: Mar. 24, 2023

(51) Int. Cl. H10K 50/19; H10K 50/15; H10K 50/16; H10K 50/818; H10K 50/828; H10K 102/00

(52) U.S. Cl. CPC H10K 50/19; H10K 50/15; H10K 50/16; H10K 50/818; H10K 50/828; H10K 2102/351

(57) ABSTRACT

The present disclosure provides a display apparatus and a display panel. The display panel includes: an anode; a cathode opposed to the anode, where one of the anode and the cathode is a reflection electrode and the other is a transmission electrode; a first light emitter, disposed between the anode and the cathode, where the first light emitter includes a first hole transport layer, a first electron transport layer and a first light-emitting structure, the first hole transport layer is opposed to the first electron transport layer, and the first light-emitting structure is disposed between the first hole transport layer and the first electron transport layer; the first light-emitting structure includes a red light-emitting layer and a first blue light-emitting layer. The present disclosure can improve luminous intensity.

### TECHNICAL FIELD

The present disclosure relates to the field of display technologies, and in particular to a display apparatus and a display panel.

### BACKGROUND

Organic Light Emitting Diode (OLED) display apparatuses are becoming a type of display apparatuses with excellent competitiveness and good development prospect at present due to a series of advantages such as full-solid-state structure, self-luminosity, fast response, high brightness, full view, flexible display or the like. But, the existing OLED display apparatuses have the problem of low luminous intensity.

### SUMMARY

The object of the present disclosure is to provide a display apparatus and a display panel so as to improve a luminous intensity.

According to an aspect of the present disclosure, there is provided a display panel, including:
an anode:
a cathode opposed to the anode, where one of the anode and the cathode is a reflection electrode while the other of the anode and the cathode is a transmission electrode:
a first light emitter disposed between the anode and the cathode, where the first light emitter includes a first hole transport layer, a first electron transport layer and a first light-emitting structure, the first hole transport layer is opposed to the first electron transport layer: the first light-emitting structure is disposed between the first hole transport layer and the first electron transport layer: the first light-emitting structure includes a red light-emitting layer and a first blue light-emitting layer.

In some embodiments, the first light-emitting structure further includes:
a carrier transport layer, the carrier transport layer is disposed on a side of the red light-emitting layer facing toward the first blue light-emitting layer, and the first blue light-emitting layer is disposed on a side of the carrier transport layer away from the red light-emitting layer.

In some embodiments, the carrier transport layer has a thickness of 2 nm to 30 nm.

In some embodiments, the red light-emitting layer is disposed on a side of the first blue light-emitting layer facing toward to the anode, and a hole transport rate of the carrier transport layer is greater than an electron transport rate of the carrier transport layer; or, the red light-emitting layer is disposed on a side of the first blue light-emitting layer away from the anode, and the hole transport rate of the carrier transport layer is less than the electron transport rate of the carrier transport layer.

In some embodiments, the red light-emitting layer includes a host material and a guest material, and the guest material includes a fluorescent material.

In some embodiments, the guest material includes one or more of rubene, Nile red, ethidium bromide, Tris(2,2′-bipyridyl)ruthenium (II) chloride hexahydrate, or coumarin compound.

In some embodiments, a weight ratio of the guest material to the host material in the red light-emitting layer is 2% to 10%.

In some embodiments, the red light-emitting layer is disposed on a side of the first blue light-emitting layer facing toward the reflection electrode;
a distance between the red light-emitting layer and the reflection electrode is 190 nm to 210 nm, and/or, a distance between the first blue light-emitting layer and the reflection electrode is 192 nm to 240 nm.

In some embodiments, the red light-emitting layer is disposed on a side of the first blue light-emitting layer away from the reflection electrode;

a distance between the red light-emitting layer and the reflection electrode is 350 nm to 370 nm, and/or, a distance between the first blue light-emitting layer and the reflection electrode is 320 nm to 368 nm.

In some embodiments, the display panel further includes:
a first charge generation layer, disposed on a side of the first light emitter along a thickness direction of the display panel;
a second light emitter, disposed between the anode and the cathode and on a side of the first charge generation layer away from the first light emitter, where the second light emitter is capable of emitting green light.

In some embodiments, the second light emitter is disposed on a side of the first light emitter facing toward the reflection electrode.

In some embodiments, the second light emitter includes a green light-emitting layer, and a distance between the green light-emitting layer and the reflection electrode is 135 nm to 155 nm.

In some embodiments, the display panel further includes:
a second charge generation layer, disposed on a side of the second light emitter away from the first charge generation layer;
a third light emitter, disposed between the anode and the cathode and on a side of the second charge generation layer away from the second light emitter, where the third light emitter is capable of emitting blue light.

In some embodiments, the second light emitter is disposed on a side of the first light emitter facing toward the reflection electrode, and the third light emitter is disposed on a side of the second light emitter facing toward to the reflection electrode.

In some embodiments, the second light emitter includes a green light-emitting layer, and a distance between the green light-emitting layer and the reflection electrode is 135 nm to 155 nm, and/or,

the third light emitter includes a second blue light-emitting layer, and a distance between the second blue light-emitting layer and the reflection electrode is 100 nm to 120 nm.

According to an aspect of the present disclosure, there is provided a display apparatus, including the above display panel.

In the display apparatus and the display panel of the embodiments of the present disclosure, the first light-emitting structure is disposed between the first hole transport layer and the first electron transport layer, and includes the red light-emitting layer and the first blue light-emitting layer. Thus, the red light-emitting layer and the first blue light-emitting layer are disposed between the first hole transport layer and the first electron transport layer, that is, the red light-emitting layer and the first blue light-emitting layer are located in one light emitter. In this case, in the present disclosure, the position of the red light-emitting layer and the position of the first blue light-emitting layer can be synchronously adjusted. At the same time, since a maximum gain front cavity length of red light is approximate to a maximum gain front cavity length of blue light, the luminous intensity of the red light and the luminous intensity of the blue light can be adjusted synchronously in the present disclosure, so as to improve the luminous intensity and luminous efficiency of the display panel, thus helping achieve high color gamut.

### BRIEF DESCRIPTION OF THE DRAWINGS

FIG. 1 is a schematic diagram illustrating a display panel in the related arts.

FIG. 2 is another schematic diagram illustrating a display panel in the related arts.

FIG. 3 is a schematic diagram illustrating a relationship between a front cavity length and an intensity of light.

FIG. 4 is a schematic diagram illustrating a display panel according to an embodiment of the present disclosure.

FIG. 5 is a schematic diagram illustrating carrier transport of a display panel according to an embodiment of the present disclosure.

FIG. 6 is a diagram illustrating a light emission principle of a display panel according to an embodiment of the present disclosure.

FIG. 7 is a diagram illustrating luminous spectra obtained under a current density of 30J in a control embodiment and an implementation embodiment.

FIG. 8 illustrates a curve of change of a device CIE (x, y) along with device brightness in a control embodiment and an implementation embodiment.

FIG. 9 illustrates a curve of change of a device efficiency along with device current density in a control embodiment and an implementation embodiment.

Numerals of the drawings are described below: 1 anode, 3 third light emitter, 301 third hole injection layer, 302 third hole transport layer, 303 third electron blocking layer, 304 second blue light-emitting layer, 305 third hole blocking layer, 306 third electron transport layer, 4 second light emitter, 401 second hole injection layer, 402 second hole transport layer, 403 second electron blocking layer, 404 green light-emitting layer, 405 second hole blocking layer, 406 second electron transport layer, 5 second charge generation layer, 6 first charge generation layer, 7 first light emitter, 701 first hole injection layer, 702 first hole transport layer, 703 first electron blocking layer, 704 red light-emitting layer, 705 carrier transport layer, 706 first blue light-emitting layer, 707 first hole blocking layer, 708 first electron transport layer, 709 first electron injection layer, 8 cathode, 9 carrier function layer, 10 first light-emitting layer, 11 second light-emitting layer, 1101 first sub-light-emitting layer, 1102 second sub-light-emitting layer, 12 third light-emitting layer.

### DETAILED DESCRIPTION OF THE EMBODIMENTS

Exemplary embodiments will be described in detail herein, with the illustrations thereof represented in the drawings. When the following descriptions involve the drawings, like numerals in different drawings refer to like or similar elements unless otherwise indicated. The embodiments described in the following examples do not represent all embodiments consistent with the present disclosure. Rather, they are merely examples of apparatuses consistent with some aspects of the present disclosure as detailed in the appended claims.

Terms used herein are used to only describe a particular embodiment rather than limit the present disclosure. Unless otherwise defined, technical terms or scientific terms used in the present disclosure should have general meanings that can be understood by ordinary persons of skill in the art. The “first”, “second” or the like used in the specification and claims do not represent any sequence, quantity or importance, but distinguish different components. Similarly, “one” or “a” and the like do not represent quantity limitation but represent at least one. “Multiple” or “a plurality” represents two or more. Unless otherwise stated, the words such as “front”, “rear”, “lower” and/or “upper” are used only for ease of descriptions rather than limited to one position or a spatial orientation. Unless otherwise stated, “include” or “contain” or the like is intended to refer to that an element or object appearing before “include” or “contain” covers an element or object or its equivalents listed after “include” or “contain” and does not preclude other elements or objects. “Connect” or “connect with” or the like is not limited to physical or mechanical connection but includes direct or indirect electrical connection. The singular forms such as “a”, “said”, and “the” used in the present disclosure and the appended claims are also intended to include plural forms, unless the context clearly indicates otherwise. It is also to be understood that the term “and/or” as used herein refers to and includes any or all possible combinations of one or more associated listed items.

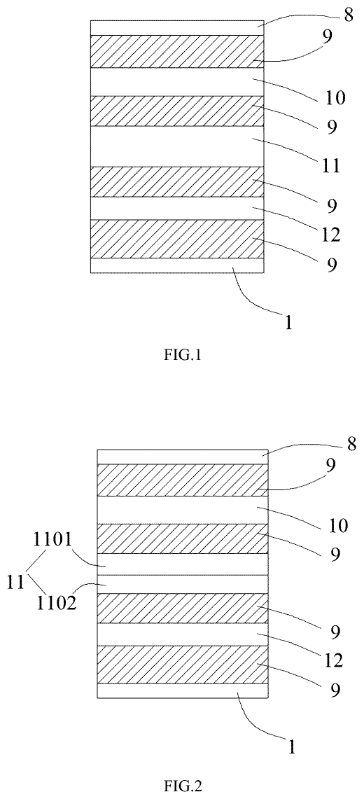

In the related arts, a white OLED may include 1-Stack WOLED, Tandem WOLED and 3Stack WOLED. FIGS. 1 and 2 are structural schematic diagrams illustrating 3Stack WOLED, including an anode 1, a first light-emitting layer 10, a second light-emitting layer 11, a third light-emitting layer 12, a carrier function layer 9 and a cathode 8. The anode 1 may be a reflection electrode and the cathode 8 may be a transmission electrode. The anode 1 and the cathode 8 can form a microcavity. The carrier function layer 9 may include an electron transport layer and a hole transport layer etc. The first light-emitting layer 10 and the third light-emitting layer 12 may be blue light-emitting layers. As shown in FIG. 1, the second light-emitting layer 11 may be a yellow light-emitting layer; as shown in FIG. 2, the second light-emitting layer 11 includes a first sub-light-emitting layer 1101 and a second sub-light-emitting layer 1102, where the first sub-light-emitting layer 1101 may be a green light-emitting layer and the second sub-light-emitting layer 1102 may be a red light-emitting layer. Considering the intrinsic attributes of the excitons, the blue light-emitting layer including a phosphorescent material has poor stability and hence, the blue light-emitting layer can be made of a material including a fluorescent material. Further, to guarantee the brightness and efficiency of the white light device, the green light-emitting layer and the red light-emitting layer both can be made of a material including a phosphorescent material. The excitons in the red light-emitting layer and the green light-emitting layer made of a phosphorescent material are triplet excitons, where the triplet excitons have long service life and long diffusion distance. When the device has a different working current or is aging, the device may easily produce a severe color deviation. The light emission of the green light-emitting layer is a major contributor to the efficiency and the brightness of the white light device. In the structure shown in FIG. 2, for the light emission of the red light-emitting layer, it is necessary to transfer an amount of energy from the green light-emitting layer to the red light-emitting layer. The transfer process brings huge energy loss to the device and the light emission of the red light-emitting layer makes low contribution to the efficiency of the device. Therefore, the device cannot achieve a desired efficiency.

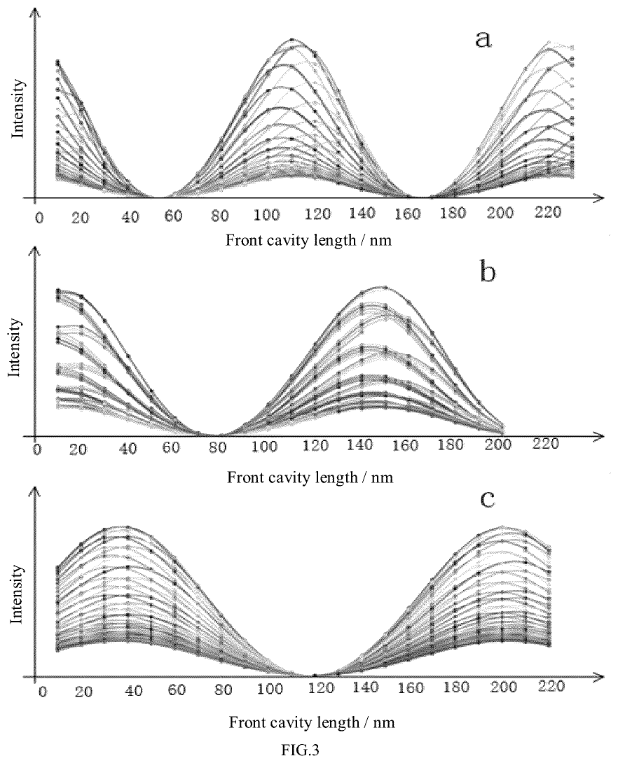

Furthermore, a distance between the light-emitting layer and the reflection electrode (a front cavity length of the microcavity) may periodically affect a gain amplitude of a wavelength. In the present disclosure, a blue light spectrum is simplified as a single-wavelength light emission at the wavelength of 460 nm, a green light spectrum is simplified as a single-wavelength light emission at the wavelength of 530 nm, and a red light spectrum is simplified as a single-wavelength light emission at the wavelength of 620 nm. As shown in the a part of FIG. 3, the blue light with the wavelength of 460 nm has an intensity peak when the front cavity length is (110 nm±n*115 nm): as shown in the b part of FIG. 3, the green light with the wavelength of 530 nm has an intensity peak when the front cavity length is (145 nm±n*130 nm): as shown in the c part of FIG. 3, the red light with the wavelength of 620 nm has an intensity peak when the front cavity length is (40 nm±n*160nm), where the above n is a positive integer greater than or equal to 1. For the lights of different colors, the front cavity length corresponding to the intensity peak may be called a maximum gain front cavity length. Hence, the maximum gain front cavity length of the blue light may be 110 nm, 225 nm or 340 nm; the maximum gain front cavity length of the green light may be 145 nm, 275 nm or 405 nm; the maximum gain front cavity length of the red light may be 200 nm, 360 nm or 520 nm. In the structure shown in FIG. 2, the red light-emitting layer and the blue light-emitting layer are almost located at a same position and thus, in the present disclosure, the luminous intensity of the red light and the luminous intensity of the blue light cannot be adjusted synchronously. Therefore, the emission of the red light and the emission of the blue light cannot be enhanced synchronously, and the target requirements of high efficiency and high color gamut cannot be achieved at the same time.

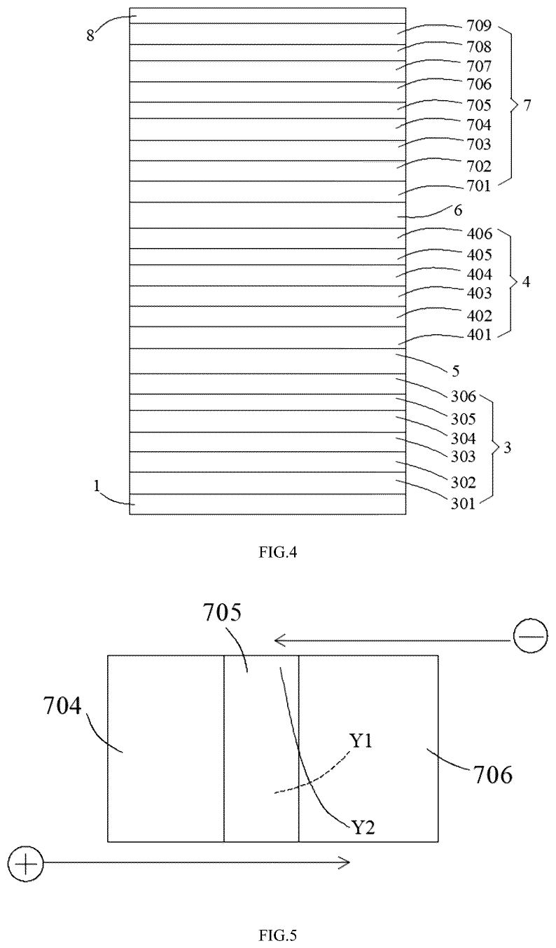

As shown in FIG. 4, an embodiment of the present disclosure provides a display panel, which may include an anode 1, a cathode 8 and a first light emitter 7.

The cathode 8 and the anode 1 are opposed to each other. One of the anode 1 and the cathode 8 is a reflection electrode while the other of the anode 1 and the cathode 8 is a transmission electrode. The first light emitter 7 is disposed between the anode 1 and the cathode 8. The first light emitter 7 includes a first hole transport layer 702, a first electron transport layer 708 and a first light-emitting structure. The first hole transport layer 702 is opposed to the first electron transport layer 708, and the first light-emitting structure is disposed between the first hole transport layer 702 and the first electron transport layer 708. The first light-emitting structure includes a red light-emitting layer 704 and a first blue light-emitting layer 706.

In the display panel of the embodiments of the present disclosure, the first light-emitting structure is disposed between the first hole transport layer 702 and the first electron transport layer 708, and includes the red light-emitting layer 704 and the first blue light-emitting layer 706. Thus, the red light-emitting layer 704 and the first blue light-emitting layer 706 are disposed between the first hole transport layer 702 and the first electron transport layer 708, that is, the red light-emitting layer 704 and the first blue light-emitting layer 706 are located in one light emitter. In this case, in the present disclosure, the position of the red light-emitting layer 704 and the position of the first blue light-emitting layer 706 can be synchronously adjusted. At the same time, since the maximum gain front cavity length of the red light is approximate to the maximum gain front cavity length of the blue light, the luminous intensity of the red light and the luminous intensity of the blue light can be adjusted synchronously in the present disclosure, so as to improve the luminous intensity and luminous efficiency of the display panel, thus helping achieve high color gamut.

The parts of the display panel in the embodiments of the present disclosure will be set forth in details.

As shown in FIG. 4, the anode 1 and the cathode 8 are opposed to each other. The anode 1 may be a reflection electrode and the cathode 8 may be a transmission electrode, and thus a microcavity can be formed between the anode 1 and the cathode 8 so as to increase the luminous intensity of the light emitter. In other embodiments of the present disclosure, the anode 1 may be a transmission electrode and the cathode 8 may be a reflection electrode. The above transmission electrode may be a transreflective electrode, which is not limited herein. For example, the anode 1 is a reflection electrode which may be formed by stacking an Ag metal layer and an ITO layer, where the Ag metal layer may have a thickness of 1000 Å, and the ITO layer may have a thickness of 100 Å to 150 Å. The cathode 8 is a transmission electrode which may be an Mg/Ag electrode, where the Mg/Ag electrode has a thickness of 100 Å to 150 Å.

The display panel of the present disclosure further includes a drive backplate. The anode 1 may be disposed on the drive backplate. The drive backplate may include a base and a drive circuit layer. The base may be a rigid base, where the rigid base may be a glass base or a Polymethyl methacrylate (PMMA) base or the like. In some embodiments, the base may be a flexible base, where the flexible base may be a Polyethylene terephthalate (PET) base, a Polyethylene naphthalate two formic acid glycol ester (PEN) base or a Polyimide (PI) base. The drive circuit layer may be disposed on the base. The drive circuit layer may include a plurality of drive transistors. These drive transistors may be thin film transistors, which is not limited in the embodiments of the present disclosure. The thin film transistor may be a top-gate thin film transistor. In some embodiments, the thin film transistor may be a bottom-gate thin film transistor. With the thin film transistor as a top-gate thin film transistor, the drive circuit layer may include an active layer, a gate insulation layer, a gate electrode, an interlayer insulation layer, a source electrode, and a drain electrode. The active layer may be disposed on the base. The gate insulation layer may be disposed on the base and covered on the active layer. The gate electrode may be disposed on a side of the gate insulation layer away from the base. The interlayer insulation layer may be disposed on the gate insulation layer and covered on the gate electrode. The source electrode and the drain electrode may be disposed on the interlayer insulation layer and connected to the active layer through via holes penetrating through the interlayer insulation layer and the gate insulation layer. In some embodiments, the drive backplate may further include a planarization layer. The planarization layer may be disposed on a surface of the drive circuit layer away from the base and covered on the source electrode and the drain electrode of the above drive transistor. The anode 1 may be disposed on the planarization layer and connected to the source electrode or the drain electrode of the drive transistor through a via hole penetrating through the planarization layer.

The first light emitter 7 may be disposed on a side of the anode 1 away from the base. The first light emitter 7 includes a first hole transport layer 702, a first electron transport layer 708, and a first light-emitting structure. The first hole transport layer 702 is disposed on a side of the anode 1 away from the base, the first light-emitting structure is disposed on a side of the first hole transport layer 702 away from the anode 1, and the first electron transport layer 708 is disposed on a side of the first light-emitting structure away from the anode 1. The first light emitter 7 may further include a first hole injection layer 701, a first electron blocking layer 703, a first electron injection layer 709 and a first hole blocking layer 707. The first hole injection layer 701 may be disposed between the first hole transport layer 702 and the anode 1, the first electron blocking layer 703 may be disposed between the first hole transport layer 702 and the first light-emitting structure, the first electron injection layer 709 may be disposed between the first electron transport layer 708 and the cathode 8, and the first hole blocking layer 707 may be disposed between the first electron transport layer 708 and the first light-emitting structure.

The first light-emitting structure includes the red light-emitting layer 704 and the first blue light-emitting layer 706. The red light-emitting layer 704 may be disposed on a side of the first blue light-emitting layer 706 facing toward the anode 1. In some embodiments, the red light-emitting layer 704 may be disposed on a side of the first blue light-emitting layer 706 away from the anode 1. For example, if the red light-emitting layer 704 is disposed on a side of the first blue light-emitting layer 706 facing toward the anode 1 which is a reflection electrode, a distance between the red light-emitting layer 704 and the reflection electrode may be 190 nm to 210 nm, for example, 190 nm, 195 nm, 200 nm, 205 nm, 210 nm or the like; a distance between the first blue light-emitting layer 706 and the reflection electrode may be 192 nm to 240 nm, for example, 192 nm, 210 nm, 220 nm, 225 nm, 240 nm or the like. For example, if the red light-emitting layer 704 is disposed on a side of the first blue light-emitting layer 706 away from the anode 1 which is a reflection electrode, a distance between the red light-emitting layer 704 and the reflection electrode may be 350 nm to 370 nm, for example, 350 nm, 355 nm, 360 nm, 365 nm, 370 nm or the like; a distance between the first blue light-emitting layer 706 and the reflection electrode may be 320 nm to 368 nm, for example, 320 nm, 330 nm, 340 nm, 350 nm, 360 nm, 368 nm or the like.

The above red light-emitting layer 704 may include a host material and a guest material. The guest material of the red light-emitting layer 704 may include a fluorescent material. In some embodiments, the fluorescent material may include one or more of rubene, Nile red, ethidium bromide, Tris(2,2′-bipyridyl)ruthenium (II) chloride hexahydrate (CAS number: 50525-27-4), or coumarin compound, which is not limited in the present disclosure. The host material of the red light-emitting layer 704 may be a metal chelate compound, a distyrylbenzene derivative, an aromatic amine derivative, a dibenzofuran derivative, or another type of material, which is not limited in the present disclosure. In other embodiments of the present disclosure, the red light-emitting layer 704 may include double host materials, for example, include N type and P type of host materials. In some embodiments, a ratio between a weight of the guest material in the red light-emitting layer 704 and a weight of the host material in the red light-emitting layer 704 may be 2% to 10%, for example, 2%, 5%, 7%, 8%, 10% or the like.

The first blue light-emitting layer 706 may be doped with a fluorescent material. The fluorescent material doped in the first blue light-emitting layer 706 may include 4,4-bis(9-carbazolyl)biphenyl (CPB), or may include dihydroethidium or the like. The first blue light-emitting layer 706 may further include double host materials, such as N type and P type of host materials. The P type material is selected from one or more of a triarylamine derivative, a carbazole derivative, a fused carbazole derivative, a carbazole triphenylene derivative, dibenzofuran or a benzofuranyl dibenzofuran derivative. The N type material is selected from one or more of a triazine derivative, a pyrimidine derivative, a diazaphosphole derivative, an electron-deficient heteroaromatic group-substituted indolocarbazole derivative, or an electron-deficient heteroaromatic group-substituted indeno carbazole derivative.

Considered from device stability, compared with phosphorescent triplet excitons with millisecond-level life, the nanosecond-picosecond-level fluorescent singlet excitons in the red light-emitting layer 704 and the first blue light-emitting layer 706 have a short life and a short diffusion distance. Hence, the recombination luminescent centers in the red light-emitting layer 704 and the first blue light-emitting layer 706 are very stable under high and low current densities, showing the device CIE(x,y) remains stable under high and low currents and after and before device aging.

In an embodiment of the present disclosure, the first light-emitting structure may further include a carrier transport layer 705. The carrier transport layer 705 may be disposed on a surface of the red light-emitting layer 704 facing toward the first blue light-emitting layer 706, and the first blue light-emitting layer 706 may be disposed on a surface of the carrier transport layer 705 away from the red light-emitting layer 704. For example, if the red light-emitting layer 704 is disposed on a side of the first blue light-emitting layer 706 facing toward the anode 1, a hole transport rate of the carrier transport layer 705 is greater than an electron transport rate of the carrier transport layer 705, that is, the carrier transport layer 705 mainly functions as a “hole transport layer”. For example, if the red light-emitting layer 704 is disposed on a side of the first blue light-emitting layer 706 away from the anode 1, a hole transport rate of the carrier transport layer 705 is less than an electron transport rate of the carrier transport layer 705, that is, the carrier transport layer 705 mainly functions as a “electron transport layer”. The carrier transport layer 705 may have a thickness of 2 nm to 30 nm. In some embodiments, the carrier transport layer 705 may have a thickness of 2 nm to 20 nm, for example, 2 nm, 9 nm, 15 nm, 18 nm, 20 nm etc.

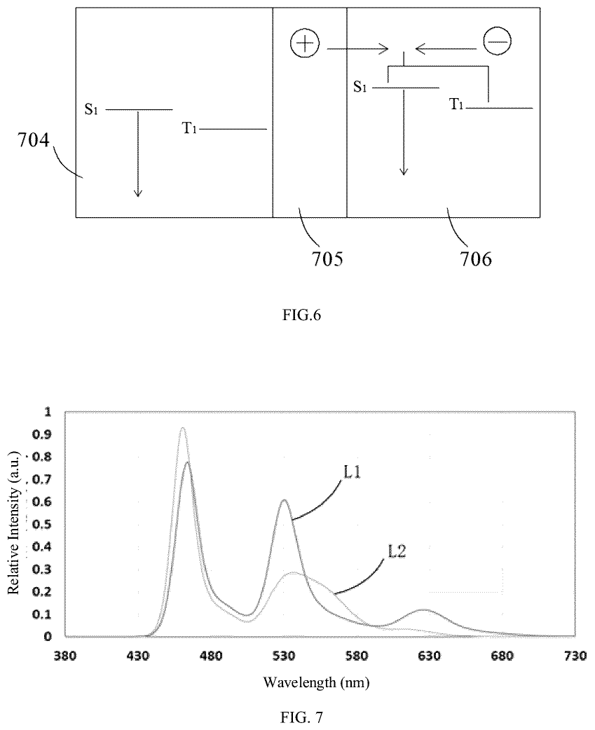

For example, if the red light-emitting layer 704 is disposed on a side of the first blue light-emitting layer 706 facing toward the anode 1, a curve of concentration of holes transported in the display panel is shown as a curve Y2 in FIG. 5, where the concentration of holes gradually decreases along a direction pointing from the carrier transport layer 705 to the first blue light-emitting layer 706; a curve of concentration of electrons transported in the display panel is shown as a curve Y1 in FIG. 5, where the concentration of electrons gradually decreases along a direction pointing from the first blue light-emitting layer 706 to the carrier transport layer 705. It can be known from FIG. 5 that the hole concentration is greater than the electron concentration in the carrier transport layer 705, which indicates the hole transport rate of the carrier transport layer 705 is greater the electron transport rate of the carrier transport layer 705; meanwhile, the hole concentration in the first blue light-emitting layer 706 quickly decreases, which indicates a recombination process of the holes and the electrons mainly occurs in the first blue light-emitting layer 706. As shown in FIG. 6, the holes and the electrons are recombined in the first blue light-emitting layer 706, and singlet (S1) excitons and triplet (T1) excitons are generated in the first blue light-emitting layer 706. The first blue light-emitting layer 706 is doped with a fluorescent material, and thus the triplet (T1) excitons have to achieve thermal energy loss by non-radiation, and the singlet (S1) excitons can transition to ground state to perform radioluminescence. Further, in FIG. 6, an amount of energy generated by the first blue light-emitting layer 706 can be transferred to the red light-emitting layer 704, such that singlet (S1) excitons and triplet (T1) excitons are generated in the red light-emitting layer 704, where the singlet (S1) excitons can transition to ground state to perform radioluminescence.

In an embodiment of the present disclosure, the display panel further includes a first charge generation layer 6 and a second light emitter 4. The first charge generation layer 6 is disposed on a side of the first light emitter 7 along a thickness direction of the display panel. For example, the first charge generation layer 6 may be disposed on a side of the first hole injection layer 701 away from the first light-emitting structure, that is, the first charge generation layer 6 is disposed on a side of the first light emitter 7 facing toward the anode 1. The second light emitter 4 is disposed between the anode 1 and the cathode 8, and located at a side of the first charge generation layer 6 away from the first light emitter 7, that is, the second light emitter 4 may be disposed on a side of the first light emitter 7 facing toward the anode 1. The second light emitter 4 may include a second electron transport layer 406, a second light-emitting structure, a second hole transport layer 402, and a second hole injection layer 401. The second electron transport layer 406 may be disposed on a side of the first charge generation layer 6 away from the first hole injection layer 701, the second light-emitting structure may be disposed on a side of the second electron transport layer 406 away from the first charge generation layer 6, the second hole transport layer 402 may be disposed on a side of the second light-emitting structure away from the first charge generation layer 6, and the second hole injection layer 401 may be disposed on a side of the second hole transport layer 402 away from the first charge generation layer 6. In some embodiments, the second light emitter 4 may include a second electron blocking layer 403 and a second hole blocking layer 405. The second electron blocking layer 403 may be disposed between the second hole transport layer 402 and the second light-emitting structure. The second hole blocking layer 405 may be disposed between the second electron transport layer 406 and the second light-emitting structure. The second light emitter 4 can emit green light, that is, the second light-emitting structure may include a green light-emitting layer 404. In some embodiments, the second light emitter 4 can emit lights of other colors. The electrons required by the second light emitter to perform light emission may be injected by the first charge generation layer 6. For example, if the second light emitter 4 is disposed on a side of the first light emitter 7 facing toward the reflection electrode, a distance between the green light-emitting layer 404 and the reflection electrode may be 135 nm to 155 nm, for example, 135 nm, 138 nm, 140 nm, 145 nm, 150 nm, 155 nm or the like. The green light-emitting layer 404 may be doped with a phosphorescent material, where the phosphorescent material may be tris(2-phenylpyridine)iridium, Ir(ppy)3 (CAS number: 94928-86-6) or the like.

In the present disclosure, the display panel may further include a second charge generation layer 5 and a third light emitter 3. The second charge generation layer 5 may be disposed on a side of the second light emitter 4 away from the first charge generation layer 6. The second charge generation layer 5 may be disposed on a side of the second hole injection layer 401 away from the first charge generation layer 6. The third light emitter 3 may be disposed between the anode 1 and the cathode 8, and located at a side of the second charge generation layer 5 away from the second light emitter 4. The third light emitter 3 may include a third electron transport layer 306, a third light-emitting structure, a third hole transport layer 302 and a third hole injection layer 301. The third electron transport layer 306 may be disposed on a side of the second charge generation layer 5 away from the second hole injection layer 401, the third light-emitting structure may be disposed on a side of the third electron transport layer 306 away from the second charge generation layer 5, the third hole transport layer 302 may be disposed on a side of the third light-emitting structure away from the second charge generation layer 5, and the third hole injection layer 301 may be disposed on a side of the third hole transport layer 302 away from the second charge generation layer 5. In some embodiments, the third light emitter may further include a third electron blocking layer 303 and a third hole blocking layer 305. The third electron blocking layer 303 may be disposed between the third hole transport layer 302 and the third light-emitting structure. The third hole blocking layer 305 may be disposed between the third electron transport layer 306 and the third light-emitting structure. The third light emitter 3 can emit blue light, that is, the third light-emitting structure may include a second blue light-emitting layer 304. In some embodiments, the third light emitter can further emit lights of other colors. The electrons required by the third light emitter 3 to perform light emission may be injected by the second charge generation layer 5. For example, if the third light emitter 3 is disposed on a side of the second light emitter 4 facing toward the reflection electrode, a distance between the second blue light-emitting layer 304 and the reflection electrode is 100 nm to 120 nm, for example, 100 nm, 105 nm, 108 nm, 110 nm 115 nm, 120 nm or the like. The second blue light-emitting layer 304 may be doped with a fluorescent material, where the fluorescent material may be 4,4′-bis(9-carbazolyl)biphenyl (CPB) or dihydroethidium or the like. The second blue light-emitting layer 304 and the first blue light-emitting layer 706 may be doped with a same fluorescent material or different fluorescent materials. The host material of the second blue light-emitting layer 304 may be same as or different from the host material of the first blue light-emitting layer 706.

The electron transport layer may be made of a material including a benzimidazole derivative, an oxadiazole derivative, a quinoxaline derivative, or another type of electron transport material, which is not limited in the present disclosure. The electron injection layer may be made of a material including an alkali metal sulfide, an alkali metal halide or other inorganic materials, or may be made of a material including a complex of alkali metal and organic substance. The hole transport layer may be made of a material including a carbazole polymer, a carbazole-connected triarylamine compound or another type of compound. The hole injection layer may be made of a material including a benzidine derivative, a star burst-shaped arylamine compound, a phthalocyanine derivative or the like.

In an embodiment of the present disclosure, the display panel may include a plurality of pixel units distributed in an array. Each of the pixel units may include the anode 1, the cathode 8, the first light emitter 7, the second light emitter 4, and the third light emitter 3, that is, the display panel is a white organic light-emitting diode (W-OLED) display panel. Respective pixel units may share one cathode 8, which is not limited in the embodiments of the present disclosure. Each pixel unit may include its own anode 1, that is, a plurality of pixel units do not share the anode 1. In some embodiments, the display panel may further include a color film substrate disposed at a light-emitting side of the pixel unit to adjust the color of the emitted light of the pixel unit. In some embodiments, the color film substrate may include a plurality of color-resist blocks, where the plurality of color-resist blocks are provided at the light-emitting sides of the plurality of pixel units in one-to-one correspondence. The plurality of color-resist blocks may include one or more red color-resist blocks, one or more blue color-resist blocks, one or more green color-resist blocks, or the like.

An embodiment of the present disclosure provides a display apparatus which includes the display panel according to any one of the above embodiments. The display apparatus may be a smart phone, a laptop computer, a television or the like. Since the display panel included in the display apparatus in the embodiments of the present disclosure is identical to the display panel in the above embodiments of the display panel, same beneficial effects can be produced and will not be repeated herein.

### Performance Test

With the structure shown in FIG. 2 as a control embodiment and the structure shown in FIG. 4 as an implementation embodiment, performance test is performed for the control embodiment and the implementation embodiment, where each film layer is formed by thermal evaporation with a cavity vacuum degree being 3×10⁶ Torr and an evaporation rate being 0.8 nm/s to 1.2 nm/s. A thickness of the film layer is measured by XP-2 step profiler. To ensure accuracy of a test result, the device is encapsulated. The encapsulation method used in the test is as follows: covering a region to be encapsulated with a glass cover plate, applying ultraviolet curing adhesive around the cover plate, and irradiating it under the ultraviolet lamp of 265 nm for 20 to 25 minutes. In the above evaporation process, for the cathode, a metal mask is used and an evaporation rate is 0.3 nm/s; and for other layers, an open mask is used and an evaporation rate is 0.1 nm/s; a luminous area of the device is 2 mm×2 mm.

FIG. 7 shows luminous spectra obtained under a current density of 30J in the control embodiment and the implementation embodiment. From the spectrum diagram, it can be seen that, compared with the control embodiment (line L2), the red light and the green light in the implementation embodiment (line L1) have a noticeably stronger luminous intensity, that is, the red light intensity and the green light intensity can be increased at the same time.

FIG. 8 illustrates a curve of change of the device CIE (x, y) along with device brightness. It can be seen that although the difference between the change amount of the CIE x (line L6) in the implementation embodiment and the change amount of CIE x (line L5) in the control embodiment is small, the change amount of the CIE y (line L4) in the implementation embodiment is much smaller than the change amount of the CIE y (line L3) in the control embodiment, which indicates the color point stability of the implementation embodiment is improved much over the white light device of the control embodiment.

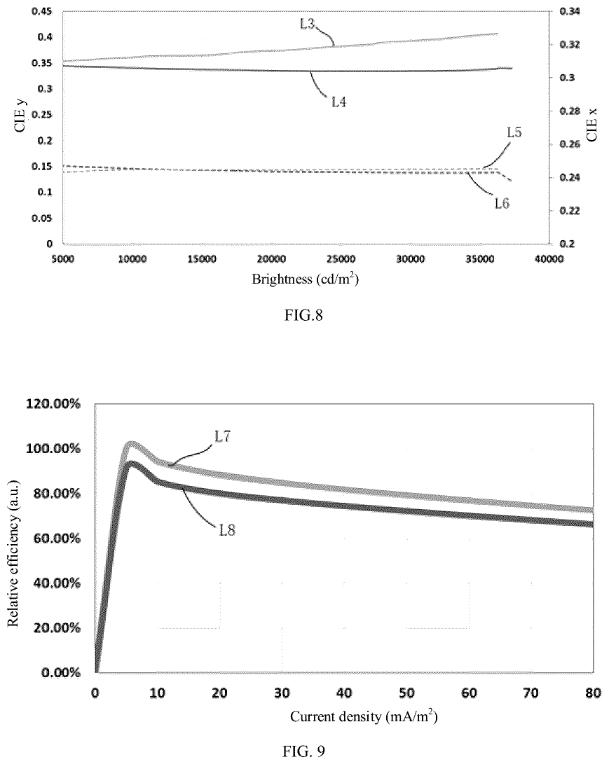

FIG. 9 illustrates a curve of change of a device efficiency along with a device current density. It can be known that the white light efficiency of the implementation embodiment (line L7) is higher than that of the control embodiment (line L8).

The above descriptions are made merely to preferred embodiments of the present disclosure rather than intended to limit the present disclosure in any manner. Although the present disclosure is made with preferred embodiments as above, these preferred embodiments are not used to limit the present disclosure. Those skilled in the art may make some changes or modifications to the technical contents of the present disclosure as equivalent embodiments without departing from the scope of the technical solution of the present disclosure. Any simple changes, equivalent changes or modifications made to the above embodiments based on the technical essence of the present disclosure without departing from the contents of the technical solution of the present disclosure shall all fall within the scope of protection of the present disclosure.

1. A display panel, comprising:
an anode;
a cathode opposed to the anode, wherein one of the anode and the cathode is a reflection electrode while the other of the anode and the cathode is a transmission electrode;
a first light emitter disposed between the anode and the cathode, wherein
the first light emitter comprises a first hole transport layer, a first electron transport layer and a first light-emitting structure,
the first hole transport layer is opposed to the first electron transport layer;
the first light-emitting structure is disposed between the first hole transport layer and the first electron transport layer;
the first light-emitting structure comprises a red light-emitting layer and a first blue light-emitting layer.

2. The display panel of claim 1, wherein the first light-emitting structure further comprises a carrier transport layer,
the carrier transport layer is disposed on a side of the red light-emitting layer facing toward the first blue light-emitting layer, and
the first blue light-emitting layer is disposed on a side of the carrier transport layer away from the red light-emitting layer.

3. The display panel of claim 2, wherein the carrier transport layer has a thickness of 2 nm to 30 nm.

4. The display panel of claim 2, wherein
the red light-emitting layer is disposed on a side of the first blue light-emitting layer facing toward to the anode, and a hole transport rate of the carrier transport layer is greater than an electron transport rate of the carrier transport layer.

5. The display panel of claim 1, wherein the red light-emitting layer comprises a host material and a guest material, and the guest material comprises a fluorescent material.

6. The display panel of claim 5, wherein the guest material comprises one or more of rubene, Nile red, ethidium bromide, Tris(2,2′-bipyridyl)ruthenium (II) chloride hexahydrate, or coumarin compound.

7. The display panel of claim 5, wherein a weight ratio of the guest material to the host material in the red light-emitting layer is 2% to 10%.

8. The display panel of claim 1, wherein
the red light-emitting layer is disposed on a side of the first blue light-emitting layer facing toward the reflection electrode;
a distance between the red light-emitting layer and the reflection electrode is 190 nm to 210 nm.

9. The display panel of claim 1, wherein
the red light-emitting layer is disposed on a side of the first blue light-emitting layer away from the reflection electrode;
a distance between the red light-emitting layer and the reflection electrode is 350 nm to 370 nm.

10. The display panel of claim 1, further comprising:
a first charge generation layer, disposed on a side of the first light emitter along a thickness direction of the display panel;
a second light emitter, disposed between the anode and the cathode and on a side of the first charge generation layer away from the first light emitter, wherein the second light emitter is capable of emitting green light.

11. The display panel of claim 10, wherein the second light emitter is disposed on a side of the first light emitter facing toward the reflection electrode.

12. The display panel of claim 11, wherein
the second light emitter comprises a green light-emitting layer, and
a distance between the green light-emitting layer and the reflection electrode is 135 nm to 155 nm.

13. The display panel of claim 10, further comprising:
a second charge generation layer, disposed on a side of the second light emitter away from the first charge generation layer; and
a third light emitter, disposed between the anode and the cathode and on a side of the second charge generation layer away from the second light emitter, wherein the third light emitter is capable of emitting blue light.

14. The display panel of claim 13, wherein
the second light emitter is disposed on a side of the first light emitter facing toward the reflection electrode, and
the third light emitter is disposed on a side of the second light emitter facing toward to the reflection electrode.

15. The display panel of claim 14, wherein
the second light emitter comprises a green light-emitting layer, and a distance between the green light-emitting layer and the reflection electrode is 135 nm to 155 nm.

16. A display apparatus, comprising the display panel comprising:
an anode;
a cathode opposed to the anode, wherein one of the anode and the cathode is a reflection electrode while the other of the anode and the cathode is a transmission electrode;
a first light emitter disposed between the anode and the cathode, wherein
the first light emitter comprises a first hole transport layer, a first electron transport layer and a first light-emitting structure,
the first hole transport layer is opposed to the first electron transport layer;
the first light-emitting structure is disposed between the first hole transport layer and the first electron transport layer;
the first light-emitting structure comprises a red light-emitting layer and a first blue light-emitting layer.

17. The display panel of claim 2, wherein
the red light-emitting layer is disposed on a side of the first blue light-emitting layer away from the anode, and the hole transport rate of the carrier transport layer is less than the electron transport rate of the carrier transport layer.

18. The display panel of claim 1, wherein
the red light-emitting layer is disposed on a side of the first blue light-emitting layer facing toward the reflection electrode;
a distance between the first blue light-emitting layer and the reflection electrode is 192 nm to 240 nm.

19. The display panel of claim 1, wherein
the red light-emitting layer is disposed on a side of the first blue light-emitting layer away from the reflection electrode;
a distance between the first blue light-emitting layer and the reflection electrode is 320 nm to 368 nm.

20. The display panel of claim 14, wherein
the third light emitter comprises a second blue light-emitting layer, and a distance between the second blue light-emitting layer and the reflection electrode is 100 nm to 120 nm.
